(19) United States
(12) Patent Application Publication
(10) Pub. No.: US 2026/0246450 A1
(43) Pub. Date: Aug. 20, 2026

(54) CASCADED BAW FILTER DIES OF DIFFERENT TECHNOLOGIES FOR PERFORMANCE IMPROVEMENT

(71) Applicant: Qorvo US, Inc., Greensboro, NC (US)

(72) Inventors: Aykut Cihangir, Munich (DE); Asdesach Zena Markos, Munich (DE)

(21) Appl. No.: 19/405,519

(22) Filed: Dec. 2, 2025

Related U.S. Application Data
(60) Provisional application No. 63/760,802, filed on Feb. 20, 2025.

(51) Int. Cl. H03H 9/54; H03H 3/02

(52) U.S. Cl. CPC H03H 9/542; H03H 3/02

(57) ABSTRACT

Embodiments of a radio frequency (RF) filter circuit are disclosed. The RF filter circuit includes a first RF circuit package and a second RF circuit package. The first RF circuit package includes a first piezoelectric substrate and the second RF circuit package includes a second piezoelectric substrate. The first piezoelectric substrate is different than the second piezoelectric substrate. For example, the first piezoelectric substrate and the second piezoelectric substrate may have different levels of doping and different electromechanical coupling coefficients. Each piezoelectric substrate has a different section of a main RF filter path, where externally accessible terminals of the first RF circuit package and the second RF circuit package couple the different sections of the main RF filter path to one another. As such, the main RF filter path is extended between the different RF circuit packages. This reduces losses experienced due to a coupling of the different piezoelectric substrates.

### RELATED APPLICATIONS

This application claims the benefit of provisional patent application serial number 63/760,802, filed February 20, 2025, the disclosure of which is hereby incorporated herein by reference in its entirety.

### FIELD OF THE DISCLOSURE

This disclosure relates generally to radio frequency (RF) filters that utilize acoustic filters.

### BACKGROUND

Bulk Acoustic Wave (BAW) filters are advanced radio frequency (RF) components that play a crucial role in modern wireless communication systems. These BAW filters operate by converting electrical energy into mechanical acoustic waves that propagate through the bulk of a piezoelectric material. BAW filters are often utilized in high frequency RF technology to provide adequate isolation between RF bands such as transmit (TX) and receive (RX) bands. Certain RF bands require a passband provided by an RF filter to have sharp transitions at one or both band edges to meet stringent suppression and isolation requirements. This is particularly crucial for TX filters, as it directly impacts some of the system's performance, such as RX band noise. Filter loss in these steep edges is a critical metric, especially when considering effects of temperature variations.

The loss in the steep edges of the passbands provided by these TX filters is primarily influenced by a Quality factor (Q-factor) of acoustic resonators. In BAW technology, higher Q-factors can be achieved with lower Scandium (Sc) content materials, such as aluminum nitride (AlN). However, these materials with lower Sc content have a drawback of lower electromechanical coupling coefficients (k2e), which affects the loss at the other band edge and in-band impedance matching.

### SUMMARY

Embodiment 1. A radio frequency (RF) filter circuit includes: a first RF circuit package includes: a first terminal externally accessible from the first RF circuit package; and a first piezoelectric substrate includes one or more first acoustic resonators and a first main RF filter path section of a main RF filter path, the first main RF filter path section is coupled to the first terminal; and a second RF circuit package includes: a second terminal externally accessible from the second RF circuit package, wherein the first terminal of the first RF circuit package is coupled to the second terminal of the second RF circuit package such that the main RF filter path is extended between the first terminal of the first RF circuit package and the second terminal of the second RF circuit package; and a second piezoelectric substrate includes one or more second acoustic resonators and a second main RF filter path section of the main RF filter path, the second main RF filter path section is coupled to the second terminal, wherein the first piezoelectric substrate is different than the second piezoelectric substrate.

Embodiment 2. The RF filter circuit of embodiment 1, wherein the first piezoelectric substrate is made from aluminum nitride (AlN) and the second piezoelectric substrate is also made from AlN, wherein the first piezoelectric substrate has a higher Scandium (Sc) doping than the second piezoelectric substrate so that the first piezoelectric substrate is different than the second piezoelectric substrate.

Embodiment 3. The RF filter circuit of embodiment 1, wherein the first piezoelectric substrate is made from AlN and the second piezoelectric substrate is also made from AlN, wherein the first piezoelectric substrate has Sc doping and the second piezoelectric substrate has no SC doping so that the first piezoelectric substrate is different than the second piezoelectric substrate.

Embodiment 4. The RF filter circuit of embodiment 1, wherein the first piezoelectric substrate is made from AlN and the second piezoelectric substrate is also made from AlN, wherein the first piezoelectric substrate has a first Sc doping and the second piezoelectric substrate has a second Sc doping wherein the first Sc doping is higher than the second Sc doping so that the first piezoelectric substrate is different than the second piezoelectric substrate.

Embodiment 5. The RF filter circuit of embodiment 1, wherein the first RF circuit package further includes a third terminal externally accessible from the first RF circuit package, wherein the first main RF filter path section of the main RF filter path is coupled between the third terminal and the first terminal.

Embodiment 6. The RF filter circuit of embodiment 5, wherein the second RF circuit package further includes a fourth terminal externally accessible from the second RF circuit package, wherein the second main RF filter path section of the main RF filter path is coupled between the second terminal and the fourth terminal.

Embodiment 7. The RF filter circuit of embodiment 6, wherein: the one or more first acoustic resonators include one or more first series resonators connected within the first main RF filter path section; and a first shunt path is connected in shunt with respect to the first main RF filter path section, the one or more first acoustic resonators includes at least one shunt resonator connected within the first shunt path.

Embodiment 8. The RF filter circuit of embodiment 7, wherein: the one or more second acoustic resonators include one or more second series resonators connected within the second main RF filter path section; and a second shunt path is connected in shunt with respect to the second main RF filter path section, the one or more second acoustic resonators includes at least one second shunt resonator connected within the second shunt path.

Embodiment 9. The RF filter circuit of embodiment 7, wherein the third terminal is configured to be coupled to an external RF signal port.

Embodiment 10. The RF filter circuit of embodiment 7, wherein the third terminal is configured to be coupled to an external RF antenna port.

Embodiment 11. A method of manufacturing an RF filter circuit includes: forming a first RF circuit package includes: a first terminal externally accessible from the first RF circuit package; and a first piezoelectric substrate includes one or more first acoustic resonators and a first main RF filter path section of a main RF filter path, the first main RF filter path section is coupled to the first terminal; forming a second RF circuit package includes: a second terminal externally accessible from the second RF circuit package; and a second piezoelectric substrate includes one or more second acoustic resonators and a second main RF filter path section of the main RF filter path, the second main RF filter path section is coupled to the second terminal, wherein the first piezoelectric substrate is different than the second piezoelectric substrate; and coupling the first terminal of the first RF circuit package to the second terminal of the second RF circuit package such that the main RF filter path extends between the first terminal of the first RF circuit package and the second terminal of the second RF circuit package.

Embodiment 12. A user element includes an RF filter circuit, wherein the RF filter circuit includes: a first RF circuit package includes: a first terminal externally accessible from the first RF circuit package; and a first piezoelectric substrate includes one or more first acoustic resonators and a first main RF filter path section of a main RF filter path, the first main RF filter path section is coupled to the first terminal; and a second RF circuit package includes: a second terminal externally accessible from the second RF circuit package, wherein the first terminal of the first RF circuit package is coupled to the second terminal of the second RF circuit package such that the main RF filter path is extended between the first terminal of the first RF circuit package and the second terminal of the first RF circuit package; and a second piezoelectric substrate includes one or more second acoustic resonators and a second main RF filter path section of the main RF filter path, the second main RF filter path section is coupled to the second terminal, wherein the first piezoelectric substrate is different than the second piezoelectric substrate.

Embodiment 13. The user element of embodiment 12, wherein the first piezoelectric substrate is made from AlN and the second piezoelectric substrate is also made from AlN, wherein the first piezoelectric substrate has a higher Sc doping than the second piezoelectric substrate so that the first piezoelectric substrate is different than the second piezoelectric substrate.

Embodiment 14. The user element of embodiment 12, wherein the first piezoelectric substrate is made from AlN and the second piezoelectric substrate is also made from AlN, wherein the first piezoelectric substrate has Scandium (Sc) doping and the second piezoelectric substrate has no SC doping so that the first piezoelectric substrate is different than the second piezoelectric substrate.

Embodiment 15. The user element of embodiment 12, wherein the first piezoelectric substrate is made from AlN and the second piezoelectric substrate is also made from AlN, wherein the first piezoelectric substrate has a first Sc doping and the second piezoelectric substrate has a second Sc doping wherein the first Sc doping is higher than the second Sc doping so that the first piezoelectric substrate is different than the second piezoelectric substrate.

Embodiment 16. The user element of embodiment 12, wherein the first RF circuit package further includes a third terminal externally accessible from the first RF circuit package, wherein the first main RF filter path section of the main RF filter path is coupled between the third terminal and the first terminal.

Embodiment 17. The user element of embodiment 16, wherein the second RF circuit package further includes a fourth terminal externally accessible from the second RF circuit package, wherein the second main RF filter path section of the main RF filter path is coupled between the second terminal and the fourth terminal.

Embodiment 18. The user element of embodiment 17, wherein: the one or more first acoustic resonators include one or more first series resonators connected within the first main RF filter path section; and a first shunt path is connected in shunt with respect to the first main RF filter path section, the one or more first acoustic resonators includes at least one shunt resonator connected within the first shunt path.

Embodiment 19. The user element of embodiment 18, wherein: the one or more second acoustic resonators include one or more second series resonators connected within the second main RF filter path section; and a second shunt path is connected in shunt with respect to the second main RF filter path section, the one or more second acoustic resonators includes at least one second shunt resonator connected within the second shunt path.

Embodiment 20. The user element of embodiment 17, wherein the third terminal is configured to be coupled to an external RF signal port.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a radio frequency (RF) filter circuit, in accordance with some embodiments;

FIG. 2 illustrates an RF filter circuit, in accordance with some embodiments;

FIG. 3 illustrates a circuit board, in accordance with some embodiments;

FIG. 4A illustrates passbands, in accordance with some embodiments;

FIG. 4B illustrates frequency responses, in accordance with some embodiments;

FIG. 5 illustrates frequency responses, in accordance with some embodiments;

FIG. 6 illustrates passbands, in accordance with some embodiments;

FIG. 7A illustrates passbands, in accordance with some embodiments;

FIG. 7B illustrates frequency responses, in accordance with some embodiments;

FIG. 7C illustrates a close up of the frequency responses shown in FIG. 7B near 1930 MHz, in accordance with some embodiments;

FIG. 8A illustrates passbands, in accordance with some embodiments;

FIG. 8B illustrates frequency responses, in accordance with some embodiments;

FIG. 8C illustrates a close up of the frequency responses shown in FIG. 8B near 1930 MHz, in accordance with some embodiments;

FIG. 9 is a flow diagram that illustrates a method of manufacturing an RF filter circuit, in accordance with some embodiments; and

FIG. 10 illustrates a user element, in accordance with some embodiments.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

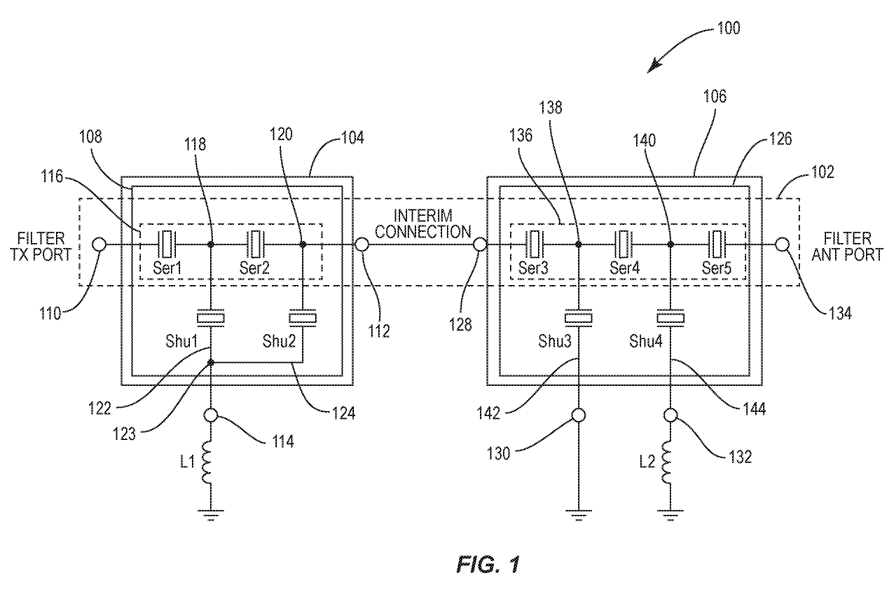

FIG. 1 illustrates a radio frequency (RF) filter circuit 100, in accordance with some embodiments.

The RF filter circuit 100 is designed to provide a proper tradeoff between a Quality factor (Q-factor) and wideband characteristics of the RF filter circuit 100, as explained below. The RF filter circuit 100 is configured to define a passband so that RF signals within the passband pass through a main RF filter path 102 while RF signals outside the passband are rejected. The Q-factor of the RF filter circuit 100 is a measure of selectivity of the passband. For example, if the Q-factor is higher, then band edges of the passband are sharper, thereby providing steeper roll off at the band edges. A bandwidth of the passband is defined by a frequency range of the passband, meaning that the higher the bandwidth, the larger the difference is between a lower band edge and a higher band edge. Doping of piezoelectric substrates has an effect on both the Q-factor and the electromechanical coupling coefficient (k2e) and, thus, a bandwidth of the RF filter circuit 100. More specifically, piezoelectric substrates that are high in doping can provide a greater bandwidth, but suffer from a lower Q-factor. Opposingly, piezoelectric substrates with lower doping can provide a higher Q-factor, but with a lower electromechanical coupling coefficient (k2e). The RF filter circuit 100 utilizes this tradeoff to provide a passband with characteristics desired for a particular application, as explained below.

The RF filter circuit 100 includes an RF circuit package 104 and an RF circuit package 106. The RF circuit package 104 may be a ball grid array (BGA), chip scale packaging (CSG), a flip chip (FC) package, a flip chip ball grid array (FCBGA), a pin grid array (PGA), a quad flat package (QFP), a ceramic substrate package, and/or the like. Similarly, the RF circuit package 106 may be a BGA, CSG, an FC package, an FCBGA, a PGA, a QFP, a ceramic substrate package, and/or the like.

The RF circuit package 104 includes a piezoelectric substrate 108 along with terminals 110, 112, 114. Each of the terminals 110, 112, 114 are externally accessible from the RF circuit package 104. A main filter path section 116 of the main RF filter path 102 is provided by the piezoelectric substrate 108. The main filter path section 116 is connected to the terminal 110 and to the terminal 112. More specifically, the main filter path section 116 is coupled between the terminal 110 and the terminal 112.

The piezoelectric substrate 108 may be made from aluminum nitride (AlN), Zinc Oxide (ZnO), lead zirconate titanate (PZT), barium strontium titanate (BST), and/or the like. In one embodiment, the piezoelectric substrate 108 is made of AlN. In some embodiments, the piezoelectric substrate 108 is made of AlN and is doped with Scandium (Sc). One piezoelectric substrate (in one example, a piezoelectric substrate 126, as will be discussed below) is formed from a first piezoelectric material having an Sc doping percentage lower than 8%, whereas another piezoelectric substrate (in one example, the piezoelectric substrate 108) is formed from a second piezoelectric material having an Sc doping percentage between 8% and 50%.

The piezoelectric substrate 108 includes acoustic resonators Ser1, Ser2, Shu1, Shu2. The acoustic resonator Ser1 is a series resonator connected in the main filter path section 116 between the terminal 110 and a node 118. The acoustic resonator Ser2 is a series resonator connected in the main filter path section 116 between the node 118 and a node 120. The node 120 is connected directly to the terminal 112. The acoustic resonator Shu1 is a shunt resonator connected in a shunt path 122. The shunt path 122 is connected to the main filter path section 116 at the node 118. The acoustic resonator Shu1 is connected between the node 118 and a node 123. The node 123 is directly connected to the terminal 114. The acoustic resonator Shu2 is a shunt resonator connected in a shunt path 124. The shunt path 124 is connected to the main filter path section 116 at the node 120. The acoustic resonator Shu2 is connected between the node 120 and the node 123. The shunt path 122 and the shunt path 124 merge at the node 123. An inductor L1 is connected to the terminal 114. The inductor L1 is connected between the terminal 114 and ground.

The RF circuit package 106 includes a piezoelectric substrate 126 along with terminals 128, 130, 132, 134. Each of the terminals 128, 130, 132, 134 are externally accessible from the RF circuit package 106. A main filter path section 136 of the main RF filter path 102 is provided by the piezoelectric substrate 126. The main filter path section 136 is connected to the terminal 128 and to the terminal 134. More specifically, the main filter path section 136 is coupled between the terminal 128 and the terminal 134. In some embodiments, the terminal 110 is configured to receive an RF signal and the terminal 134 is coupled to an antenna port.

The piezoelectric substrate 126 may be made from AlN, ZnO, PZT, BST, and/or the like. In one embodiment, the piezoelectric substrate 126 is made of AlN. In some embodiments, the piezoelectric substrate 126 is made of AlN and is doped with Sc. In some embodiments, the piezoelectric substrate 108 has an Sc doping percentage between 8% and 50%. In some embodiments, the piezoelectric substrate 126 has an Sc doping percentage of 0% (i.e., no Sc doping). In still other embodiments, the piezoelectric substrate 126 has an Sc doping percentage greater than 8% but no more than 50%. Thus, the Sc doping percentage of the piezoelectric substrate 126 is lower than the Sc doping percentage of the piezoelectric substrate 108.

In some embodiments, the piezoelectric substrates 108, 126 are each Bulk Acoustic Wave (BAW) devices or Surface Acoustic Wave (SAW) devices. The piezoelectric substrate 126 includes acoustic resonators Ser3, Ser4, Ser5, Shu3, Shu4. The acoustic resonator Ser3 is a series resonator connected in the main filter path section 136 between the terminal 128 and a node 138. The acoustic resonator Ser4 is a series resonator connected in the main filter path section 136 between the node 138 and a node 140. The acoustic resonator Ser5 is a series resonator connected in the main filter path section 136 between the node 138 and the terminal 134. The acoustic resonator Shu3 is a shunt resonator connected in a shunt path 142. The shunt path 142 is connected to the main filter path section 136 at the node 138. The acoustic resonator Shu3 is connected between the node 138 and the terminal 130. The terminal 130 can be connected to ground.

The acoustic resonator Shu4 is a shunt resonator connected in a shunt path 144. The shunt path 144 is connected to the main filter path section 136 at the node 140. The acoustic resonator Shu4 is connected between the node 140 and the terminal 132. An inductor L2 is connected to the terminal 132. The inductor L2 is connected between the terminal 132 and ground.

The terminal 112 of the RF circuit package 104 is coupled to the terminal 128 of the RF circuit package 106 such that the main RF filter path 102 is extended between the terminal 112 of the RF circuit package 104 and the terminal 128 of the RF circuit package 106. By connecting two different ones of the main filter path sections 116, 136 of the main RF filter path 102, a number of the externally accessible terminals 112, 128 used to form the RF filter circuit 100 are minimized. By minimizing the number of the externally accessible terminals 112, 128 used to form the RF filter circuit 100, the losses experienced by the RF filter circuit 100 are reduced. In this manner, the two piezoelectric substrates 108, 126 are used to form the RF filter circuit 100 with a minimum additional loss penalty. The piezoelectric substrate 108 is different than the piezoelectric substrate 126 in order to balance the tradeoff between the bandwidth and the Q-factor.

In one embodiment, the piezoelectric substrate 108 is made from AlN and the piezoelectric substrate 126 is also made from AlN. However, the piezoelectric substrate 108 has a higher level of Sc doping than the piezoelectric substrate 126 so that the piezoelectric substrate 108 is different than the piezoelectric substrate 126. In some embodiments, the piezoelectric substrate 108 has an Sc doping percentage between 8% and 50%. In some embodiments, the piezoelectric substrate 126 has an Sc doping percentage of 0% (i.e., no Sc doping). In still other embodiments, the piezoelectric substrate 126 has an Sc doping percentage greater than 8% but no more than 50%. Thus, the Sc doping percentage of the piezoelectric substrate 126 is lower than the Sc doping percentage of the piezoelectric substrate 108. Since the piezoelectric substrate 108 has a higher level of Sc doping while the piezoelectric substrate 126 provides a lower level of Sc doping, the piezoelectric substrate 108 provides a greater electromechanical coupling coefficient (k2e) and a greater bandwidth (but a lower Q-factor) while the piezoelectric substrate 126 provides a greater Q-factor (but a smaller bandwidth). By determining the number of the acoustic resonators Ser1, Ser2, Ser3, Ser4, Ser5, Shu1, Shu2, Shu3, Shu4 in each of the piezoelectric substrates 108, 126, the tradeoff between the Q-factor and the bandwidth can be provided in accordance with the demands of a particular RF application.

For example, a B25 transmit (TX) frequency band is particularly challenging for RF filters due to steep transition requirements and output power challenges. The B25 TX frequency band has an upper band edge at 1915 MHz and requires more than 60 dB suppression at 1930 MHz. Achieving such a steep transition is technically demanding and requires precise filter design. The loss at the upper band edge is an important parameter, as it directly affects the maximum current the module can handle. There is particular importance on minimizing this loss, making it a key performance metric. Achieving the required output power from the RF filter at the upper band edge requires reduced losses to maximize overall efficiency. The two piezoelectric substrates 108, 126 with different levels of Sc doping provide the balance needed for the B25 TX frequency band between the electromechanical coupling coefficient (k2e) and the Q-factor. Furthermore, losses are minimized since the external connections are minimized by connecting two different ones of the main filter path sections 116, 136 of the main RF filter path 102.

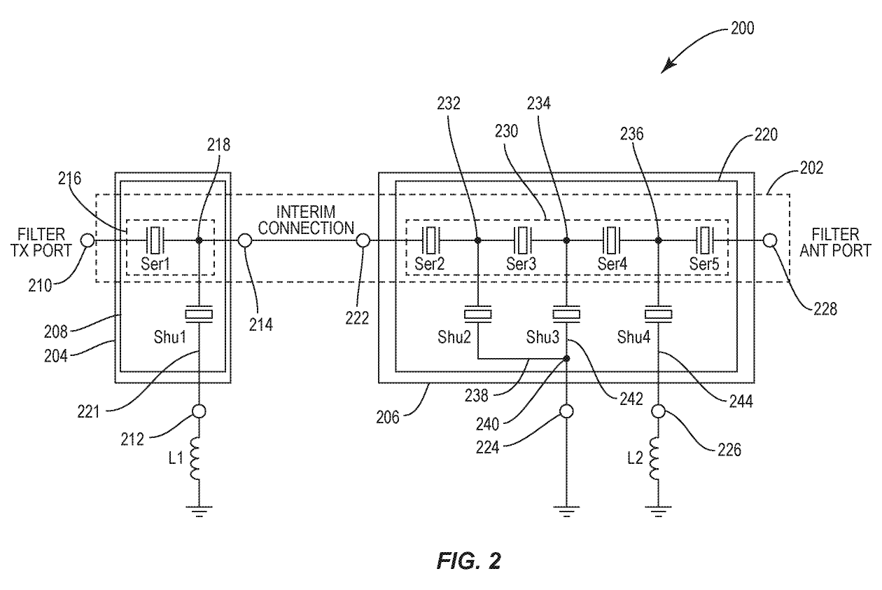

FIG. 2 illustrates an RF filter circuit 200, in accordance with some embodiments.

The RF filter circuit 200 is designed to provide a proper tradeoff between a Q-factor and wideband characteristics of the RF filter circuit 200, as explained below. The RF filter circuit 200 is configured to define a passband so that RF signals within the passband pass through a main RF filter path 202 while RF signals outside the passband are rejected. The RF filter circuit 200 utilizes the tradeoff between the Q-factor and a bandwidth to provide a passband with the characteristics desired for a particular application, as explained below.

The RF filter circuit 200 includes an RF circuit package 204 and an RF circuit package 206. The RF circuit package 204 may a BGA, CSG, an FC package, an FCBGA, a PGA, a QFP, a ceramic substrate package, and/or the like. Similarly, the RF circuit package 206 may be a BGA, CSG, an FC package, an FCBGA, a PGA, a QFP, a ceramic substrate package, and/or the like.

The RF circuit package 204 includes a piezoelectric substrate 208 along with terminals 210, 212, 214. Each of the terminals 210, 212, 214 is externally accessible from the RF circuit package 204. A main filter path section 216 of the main RF filter path 202 is provided by the piezoelectric substrate 208. The main filter path section 216 is connected to the terminal 210 and to the terminal 212. More specifically, the main filter path section 216 is coupled between the terminal 210 and the terminal 212.

The piezoelectric substrate 208 may be made from AlN, ZnO, PZT, BST, and/or the like. In one embodiment, the piezoelectric substrate 208 is made of AlN. In some embodiments, the piezoelectric substrate 208 is made of AlN and is doped with Sc. In some embodiments, the piezoelectric substrate 208 has an Sc doping percentage between 8% and 50%.

The piezoelectric substrate 208 includes the acoustic resonators Ser1, Ser2, Shu1, Shu2. However, the acoustic resonators Ser2, Shu2 are not in the piezoelectric substrate 208 in FIG. 2, unlike the piezoelectric substrate 108 in FIG. 1. The acoustic resonator Ser1 is a series resonator connected in the main filter path section 216 between the terminal 210 and a node 218. The node 218 is directly connected to the terminal 214. The acoustic resonator Shu1 is a shunt resonator connected in a shunt path 221. The shunt path 221 is connected to the main filter path section 216 at the node 218. The acoustic resonator Shu1 is connected between the node 218 and the terminal 212. The inductor L1 is connected to the terminal 212. The inductor L1 is connected between the terminal 212 and ground. It should be noted that, in other alternative embodiments, the inductor L1 is not provided and the terminal 212 is directly connected to ground.

The RF circuit package 206 includes a piezoelectric substrate 220 along with terminals 222, 224, 226, 228. Each of the terminals 222, 224, 226, 228 are externally accessible from the RF circuit package 206. A main filter path section 230 of the main RF filter path 202 is provided by the piezoelectric substrate 220. The main filter path section 230 is connected to the terminal 222 and to the terminal 228. More specifically, the main filter path section 230 is coupled between the terminal 222 and the terminal 228.

The piezoelectric substrate 220 may be made from AlN, ZnO, PZT, BST, and/or the like. In one embodiment, the piezoelectric substrate 220 is made of AlN. In some embodiments, the piezoelectric substrate 220 is made of AlN and is doped with Sc. In some embodiments, the piezoelectric substrate 220 has an Sc doping percentage between 0% and 8%. In some embodiments, the piezoelectric substrate 208 has an Sc doping percentage between 8% and 50%. Thus, the Sc doping percentage of the piezoelectric substrate 208 is higher than the Sc doping percentage of the piezoelectric substrate 220.

In some embodiments, the piezoelectric substrates 208, 220 are each BAW devices or SAW devices. The piezoelectric substrate 220 includes the acoustic resonators Ser2, Ser3, Ser4, Ser5, Shu2, Shu3, Shu4. The acoustic resonator Ser2 is a series resonator connected in the main filter path section 230 between the terminal 222 and a node 232. The acoustic resonator Ser3 is a series resonator connected in the main filter path section 230 between the node 232 and a node 234. The acoustic resonator Ser4 is a series resonator connected in the main filter path section 230 between the node 234 and a node 236. The acoustic resonator Ser5 is a series resonator connected in the main filter path section 230 between the node 236 and the terminal 228.

The acoustic resonator Shu2 is a shunt resonator connected in a shunt path 238 that is connected at the node 232. The acoustic resonator Shu2 is connected between the node 232 and a node 240. The acoustic resonator Shu3 is a shunt resonator connected in a shunt path 242. The shunt path 242 is connected to the main filter path section 230 at the node 234. The acoustic resonator Shu3 is connected between the node 234 and the node 240. The shunt path 238 and the shunt path 242 merge at the node 240. The node 240 is directly connected to the terminal 224. The terminal 224 is connected directly to ground.

The acoustic resonator Shu4 is a shunt resonator connected in a shunt path 244. The shunt path 244 is connected to the main filter path section 230 at the node 236. The acoustic resonator Shu4 is connected between the node 236 and the terminal 226. The inductor L2 is connected to the terminal 226. The inductor L2 is connected between the terminal 226 and ground.

The terminal 214 of the RF circuit package 204 is coupled to the terminal 222 of the RF circuit package 206 such that the main RF filter path 202 is extended between the terminal 214 of the RF circuit package 204 and the terminal 222 of the RF circuit package 206. By connecting two different ones of the main filter path sections 216, 230 of the main RF filter path 202, a number of the externally accessible terminals 214, 222 used to form the RF filter circuit 200 are minimized. By minimizing the number of the externally accessible terminals 214, 222 used to form the RF filter circuit 200, the losses of the RF filter circuit 200 are reduced. In this manner, the two piezoelectric substrates 208, 220 are used to form the RF filter circuit 200. The piezoelectric substrate 208 is different than the piezoelectric substrate 220 in order to balance the tradeoff between the electromechanical coupling coefficient (k2e) and the Q-factor.

In one embodiment, the piezoelectric substrate 208 is made from AlN and the piezoelectric substrate 220 is also made from AlN. However, the piezoelectric substrate 208 has a higher level of Sc doping than the piezoelectric substrate 220 so that the piezoelectric substrate 208 is different than the piezoelectric substrate 220. In some embodiments, the piezoelectric substrate 220 has an Sc doping percentage between 0% and 8%. In some embodiments, the piezoelectric substrate 208 has an Sc doping percentage between 8% and 50%. Thus, the Sc doping percentage of the piezoelectric substrate 208 is higher than the Sc doping percentage of the piezoelectric substrate 220. Since the piezoelectric substrate 208 has a higher level of Sc doping while the piezoelectric substrate 220 provides a lower level of Sc doping, the piezoelectric substrate 208 provides a greater electromechanical coupling coefficient (k2e) (but a lower Q-factor) while the piezoelectric substrate 220 provides a greater Q-factor (but a smaller bandwidth).

By comparing the RF filter circuit 100 in FIG. 1 with the RF filter circuit 200 in FIG. 2, one can see that, in FIG. 1, the acoustic resonators Ser2, Shu2 are in the piezoelectric substrate 108 with the higher level of Sc doping. In FIG. 2, the acoustic resonators Ser2, Shu2 are in the piezoelectric substrate 220 with the lower level of Sc doping. Thus, in FIG. 1, the RF filter circuit 100 weighs the tradeoff between the electromechanical coupling coefficient (k2e) and the Q-factor further towards the bandwidth while, in FIG. 2, the RF filter circuit 200 weighs the tradeoff between the bandwidth and the Q-factor further towards the steeper roll off provided by the Q-factor.

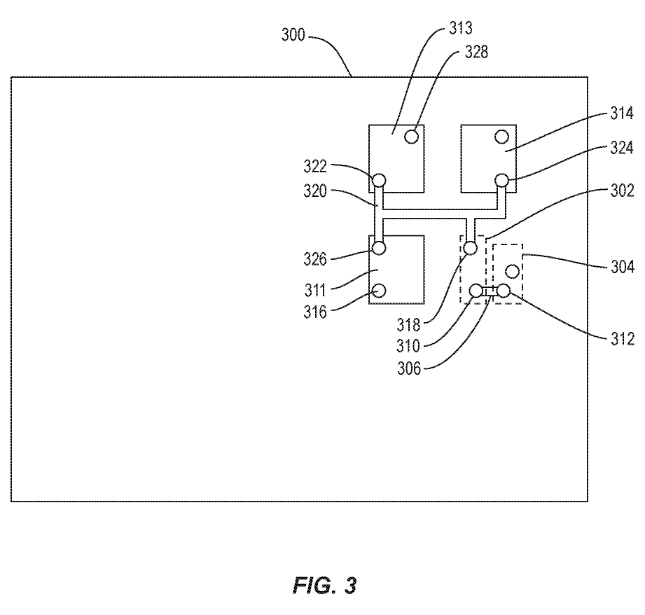

FIG. 3 illustrates a circuit board 300, in accordance with some embodiments.

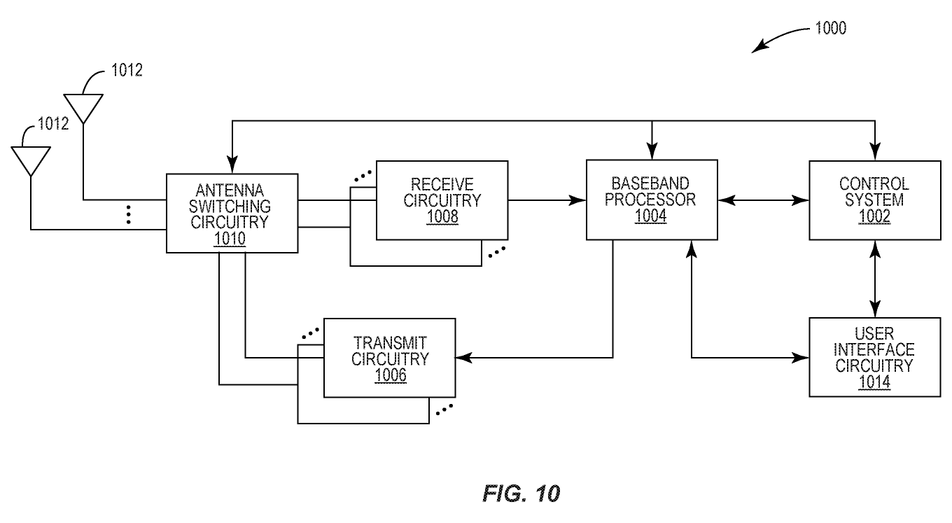

In some embodiments, the circuit board 300 may be provided in a user element 1000 discussed below in FIG. 10. An RF circuit package 302 is mounted on the circuit board 300 and an RF circuit package 304 is mounted on the circuit board 300. In some embodiments, the RF circuit package 302 is either the RF circuit package 104 in FIG. 1 or the RF circuit package 204 in FIG. 2. In some embodiments, the RF circuit package 304 is the RF circuit package 106 in FIG. 1 and the RF circuit package 206 in FIG. 2.

The combination of the RF circuit package 302 and the RF circuit package 304 can be fit into similar sized areas on the circuit board 300 in comparison with standard ladder topology filter dies. Note that the RF circuit package 302 is connected by an external connection 306 between an external terminal 310 of the RF circuit package 302 and an external terminal 312 of the RF circuit package 304. In some embodiments, the external terminal 310 corresponds to the terminal 112 of the RF circuit package 104 and the external terminal 312 corresponds to the terminal 128 of the RF circuit package 106. In some embodiments, the external terminal 310 corresponds to the terminal 214 shown in FIG. 2 and the external terminal 312 corresponds to the terminal 222 shown in FIG. 2. Furthermore, in some embodiments, the RF circuit package 302 and the RF circuit package 304 correspond to a filter for the B25 TX frequency band, as was explained above with respect to FIGS. 1 and 2.

It should be noted that other components may be mounted to the circuit board 300. More specifically, the circuit board 300 may include RF switches (not explicitly shown), amplifiers (not explicitly shown), and other additional filter circuitry. In this embodiment, the additional filter circuitry includes an RF circuit package 313, an RF circuit package 314, and an RF circuit package 316 that are utilized for RF carrier bands. The RF circuit package 302 includes an external terminal 318. The external terminal 318 corresponds with the terminal 134 shown in FIG. 1 and the terminal 228 shown in FIG. 2, in accordance with some embodiments. An external connection 320 connects the external terminal 318 to an external terminal 322 in the RF circuit package 313, an external terminal 324 of the RF circuit package 314, and an external terminal 326 of the RF circuit package 316. In some embodiments, the external terminal 322 of the RF circuit package 313 is an antenna terminal. In some embodiments, the RF circuit package 313 further includes an external terminal 328 that is a TX/receive (/RX) terminal.

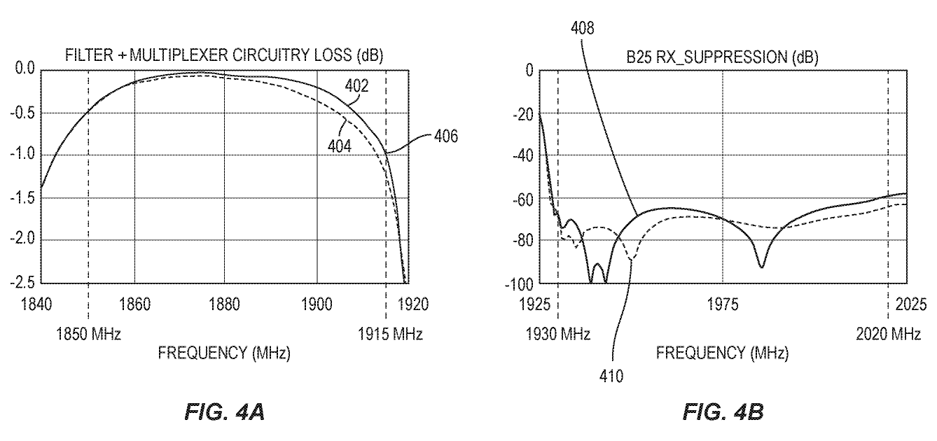

FIG. 4A illustrates passbands 402, 404, in accordance with some embodiments.

The RF filter circuit 200 in FIG. 2 is configured to generate the passband 402, in accordance with some embodiments. The passband 404 is of another RF filter circuit (not shown) having a similar topology as the RF filter circuit 200, but where all of the acoustic resonators Ser1, Ser2, Ser3, Ser4, Ser5, Shu1, Shu2, Shu3, Shu4 in FIG. 2 are formed on a same piezoelectric substrate that has the same amount of Sc doping as the piezoelectric substrate 208 in FIG. 2, where the same amount of Sc doping is found throughout the whole of the piezoelectric substrate 208 and throughout the whole of the circuitry. As shown in FIG. 4A, the passband 402 has a demonstrated improvement between 0.2 dB - 0.3 dB near an upper band edge 406 of the passband 402 in comparison with the passband 404.

FIG. 4B illustrates frequency responses 408, 410, in accordance with some embodiments.

The RF filter circuit 200 in FIG. 2 is configured to generate the frequency response 408, in accordance with some embodiments. The frequency response 408 is just above the passband 402 shown in FIG. 4A. The frequency response 410 is of another RF filter circuit (not shown) having a similar topology as the RF filter circuit 200, but where all of the acoustic resonators Ser1, Ser2, Ser3, Ser4, Ser5, Shu1, Shu2, Shu3, Shu4 in FIG. 2 are formed on a same piezoelectric substrate that has the same amount of Sc doping as the piezoelectric substrate 208 in FIG. 2, where the same amount of Sc doping is found throughout the whole of the piezoelectric substrate 208 and throughout the whole of the circuitry. The frequency response 408 is just above the passband 402 in FIG. 4A and the frequency response 410 is just above the passband 404 shown in FIG. 4A. As shown in FIG. 4B, the frequency response 408 and the frequency response 410 have similar suppression levels above their respective passbands 402, 404 in FIG. 4A.

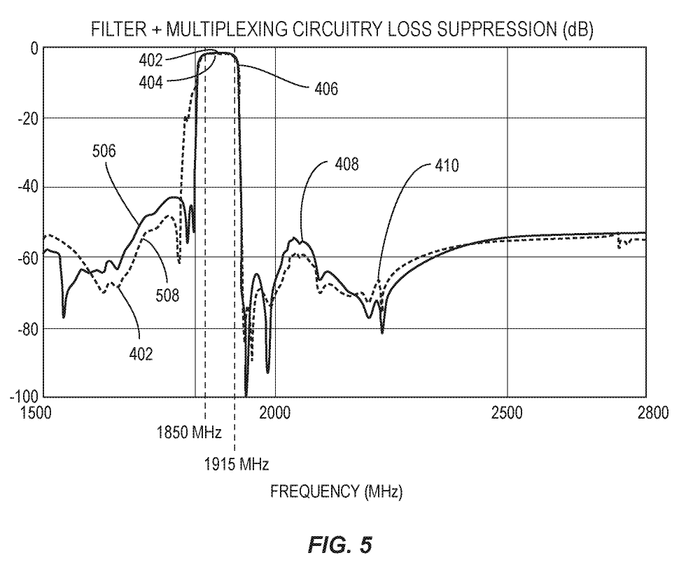

FIG. 5 illustrates frequency responses 506, 508, in accordance with some embodiments.

The RF filter circuit 200 in FIG. 2 is configured to generate the frequency response 506, in accordance with some embodiments. The frequency response 506 includes the passband 402 shown in FIG. 4A as well as the frequency response 408 shown in FIG. 4B. The frequency response 508 is of another RF filter circuit (not shown) having a similar topology as the RF filter circuit 200, but where all of the acoustic resonators Ser1, Ser2, Ser3, Ser4, Ser5, Shu1, Shu2, Shu3, Shu4 in FIG. 2 are formed on a same piezoelectric substrate that has the same amount of Sc doping as the piezoelectric substrate 208 in FIG. 2, where the same amount of Sc doping is found throughout the whole of the piezoelectric substrate 208 and throughout the whole of the circuitry. The frequency response 508 includes the passband 404 shown in FIG. 4A and the frequency response 410 shown in FIG. 4B. As shown by FIG. 5, the frequency responses 506, 508 are similar in overall out-of-band suppression characteristics. Given what is shown in FIG. 4A, FIG. 4B, and FIG. 5, an improvement between 0.2 dB - 0.3 dB is shown at the upper band edge 406 of the passband 402 as a result of the design illustrated in FIG. 2.

It should be noted that the passbands 402, 404 shown in FIG. 4A, the frequency responses 408, 410 shown in FIG. 4B, and the frequency responses 506, 508 shown in FIG. 5 were taken with an assumption that upstream circuitry was connected to the terminal 210 shown in FIG. 2 and antenna circuitry was connected to the terminal 228 shown in FIG. 2.

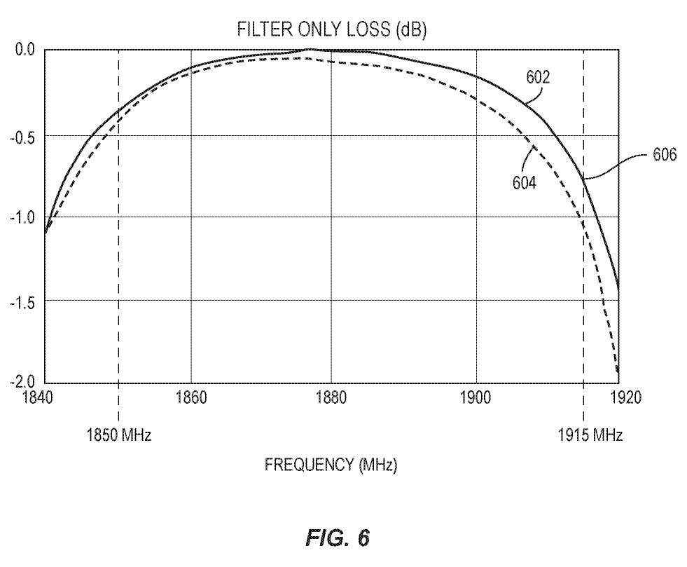

FIG. 6 illustrates passbands 602, 604, in accordance with some embodiments.

The RF filter circuit 200 in FIG. 2 is configured to generate the passband 602, in accordance with some embodiments. The passband 604 is of another RF filter circuit (not shown) having a similar topology as the RF filter circuit 200, but where all of the acoustic resonators Ser1, Ser2, Ser3, Ser4, Ser5, Shu1, Shu2, Shu3, Shu4 in FIG. 2 are formed on a same piezoelectric substrate that has the same amount of Sc doping as the piezoelectric substrate 208 in FIG. 2, where the same amount of Sc doping is found throughout the whole of the piezoelectric substrate 208 and throughout the whole of the circuitry. As shown in FIG. 6, the passband 602 has an improvement near an upper band edge 606 of the passband 602 in comparison with the passband 604. The passbands 602, 604 were measured without upstream circuitry being connected to the terminal 210 shown in FIG. 2 and without antenna circuitry being connected to the terminal 228 shown in FIG. 2. This shows that an improvement is the result of the design of the RF filter circuit 200.

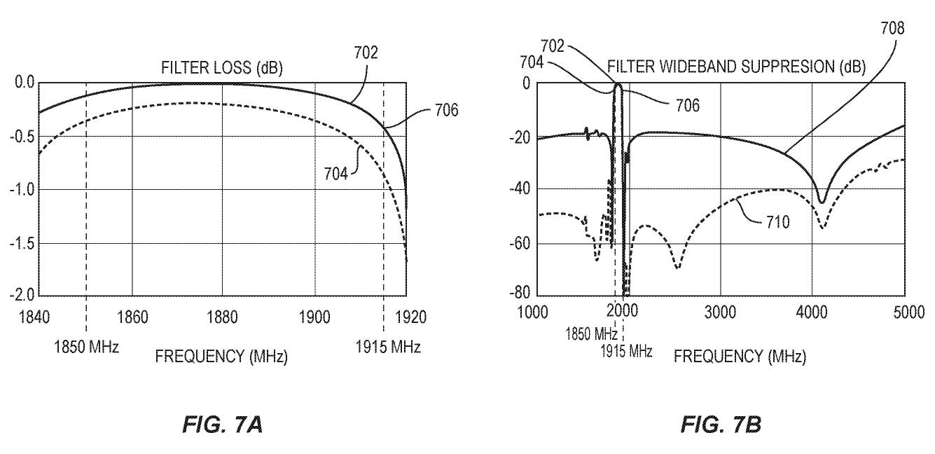

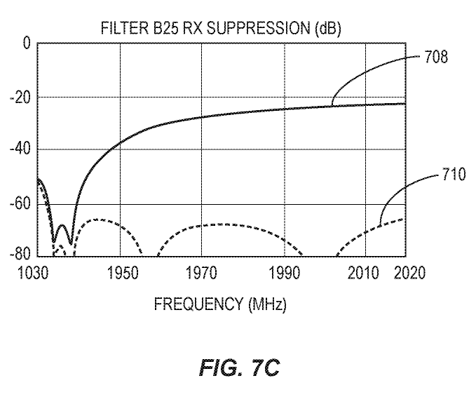

FIG. 7A illustrates passbands 702, 704, in accordance with some embodiments.

The arrangement of the acoustic resonators Ser3, Ser4, Ser5, Shu3, Shu4 in FIG. 1 in the RF circuit package 106 in FIG. 1 is configured to generate the passband 702 between the terminal 128 and the terminal 134 in FIG. 1, in accordance with some embodiments. The acoustic resonators Ser1, Ser2, Ser3, Ser4, Ser5, Shu1, Shu2, Shu3, Shu4 in FIG. 1 in the RF filter circuit 100 in FIG. 1 is configured to generate the passband 704 between the terminal 110 and the terminal 134 in FIG. 1, in accordance with some embodiments.

FIG. 7B illustrates frequency responses 708, 710, in accordance with some embodiments.

The arrangement of the acoustic resonators Ser3, Ser4, Ser5, Shu3, Shu4 in FIG. 1 in the RF circuit package 106 in FIG. 1 is configured to generate the frequency response 708 between the terminal 128 in FIG. 1 and the terminal 134 in FIG. 1, in accordance with some embodiments. The acoustic resonators Ser1, Ser2, Ser3, Ser4, Ser5, Shu1, Shu2, Shu3, Shu4 in FIG. 1 in the RF filter circuit 100 in FIG. 1 is configured to generate the frequency response 710 between the terminal 110 and the terminal 134 in FIG. 1, in accordance with some embodiments. The frequency response 708 includes the passband 702 in FIG. 7A and the frequency response 710 includes the passband 704 in FIG. 7A.

FIG. 7C illustrates a close up of the frequency responses 708, 710 shown in FIG. 7B near 1930 MHz, in accordance with some embodiments.

The frequency of 1930MHz is around an RX band for band 25. As shown by FIG. 7B and FIG. 7C, the portion of the RF filter circuit 100 in FIG. 1 in the piezoelectric substrate 126 in FIG. 1 is providing steepness at the upper band edge 706 in FIG. 7B with minimum loss thanks to the high Q-factor characteristics. Around 60 dB of suppression is provided at 1930 MHz and is coming from the portion of the RF filter circuit 100 in the piezoelectric substrate 126. By evaluating FIG. 7A, FIG. 7B, and FIG. 7C together, it is shown that the RF circuit package 106 in FIG. 1 is determining that the steep transition in the upper band edge 706 creates suppression notches around 1930MHz. The suppression contribution to other carrier aggregation (CA) band frequencies between 2000 - 2700 MHz is less significant.

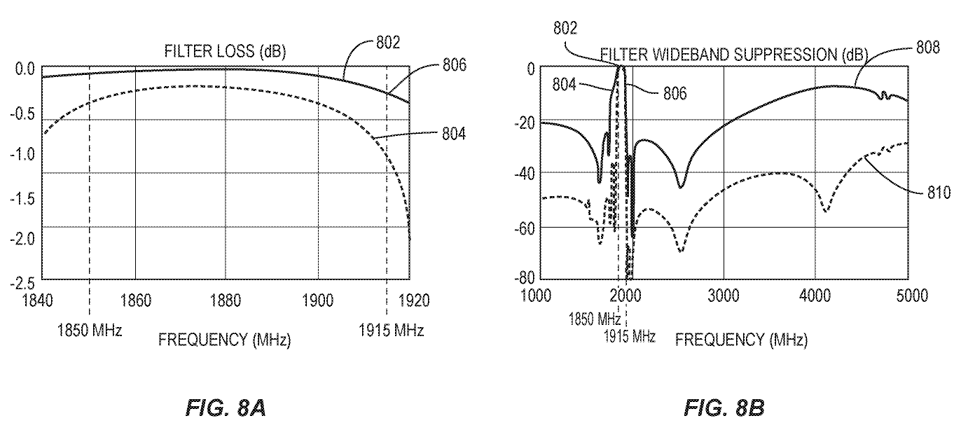

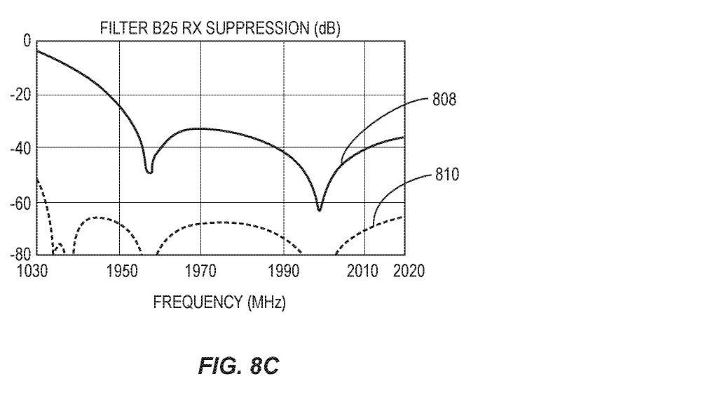

FIG. 8A illustrates passbands 802, 804, in accordance with some embodiments.

The arrangement of the acoustic resonators Ser1, Ser2, Shu1, Shu2 in FIG. 1 in the RF circuit package 104 in FIG. 1 is configured to generate the passband 802 between the terminal 110 in FIG. 1 and the terminal 112 in FIG. 1, in accordance with some embodiments. The arrangement of the acoustic resonators Ser1, Ser2, Ser3, Ser4, Ser5, Shu1, Shu2, Shu3, Shu4 in FIG. 1 in the RF filter circuit 100 in FIG. 1 is configured to generate the passband 804 between the terminal 110 in FIG. 1 and the terminal 134 in FIG. 1, in accordance with some embodiments. An upper band edge 806 of the passband 804 is shown. As shown in FIG. 8A, the RF circuit package 104 includes the portion of the RF filter circuit 100 that provides the wider bandwidth.

FIG. 8B illustrates frequency responses 808, 810, in accordance with some embodiments.

The arrangement of the acoustic resonators Ser1, Ser2, Shu1, Shu2 in FIG. 1 in the RF circuit package 104 in FIG. 1 is configured to generate the frequency response 808 between the terminal 110 in FIG. 1 and the terminal 112 in FIG. 1, in accordance with some embodiments. The arrangement of the acoustic resonators Ser1, Ser2, Ser3, Ser4, Ser5, Shu1, Shu2, Shu3, Shu4 in FIG. 1 in the RF filter circuit 100 in FIG. 1 is configured to generate the frequency response 810 between the terminal 110 in FIG. 1 and the terminal 134 in FIG. 1, in accordance with some embodiments. The frequency response 808 includes the passband 802 and the frequency response 810 includes the passband 804.

FIG. 8C illustrates a close up of the frequency responses 808, 810 shown in FIG. 8B near 1930 MHz, in accordance with some embodiments.

The frequency of 1930 MHz is around the receive band for band 25. As shown by FIG. 8B and FIG. 8C, the portion of the RF filter circuit 100 in FIG. 1 in the piezoelectric substrate 108 in FIG. 1 provides almost no suppression around 1930 MHz. This section of the circuitry provides an overall suppression in CA bands with very low loss through a whole frequency range of a transmit band for band 25.

By evaluating FIG. 8A, FIG. 8B, and FIG. 8C together, it is clear that the RF circuit package 104 does not provide any suppression notches at 1930 MHz, but rather provides suppression for the CA bands between 2000 - 2700 MHz.

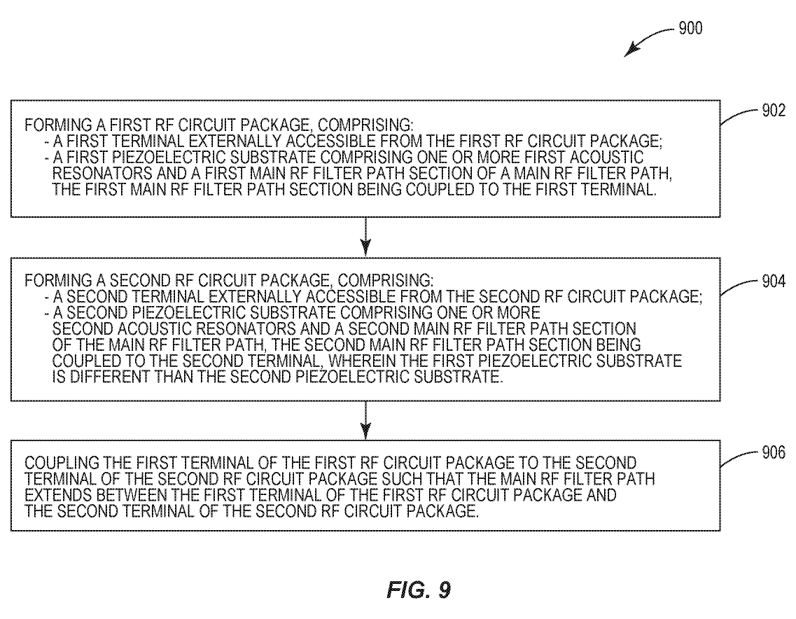

FIG. 9 is a flow diagram 900 that illustrates a method of manufacturing an RF filter circuit, in accordance with some embodiments.

In some embodiments, the flow diagram 900 is used to manufacture the RF filter circuit 100 in FIG. 1 or the RF filter circuit 200 in FIG. 2. The flow diagram 900 includes blocks 902-906. Flow begins at block 902.

At block 902, a first RF circuit package is formed. The first RF circuit package includes a first terminal externally accessible from the first RF circuit package; and a first piezoelectric substrate including one or more first acoustic resonators and a first main RF filter path section of a main RF filter path, the first main RF filter path section being coupled to the first terminal. An example of the first RF circuit package is the RF circuit package 104 in FIG. 1. An example of the first terminal is the terminal 112 in FIG. 1. An example of the main filter path is the main RF filter path 102 in FIG. 1. An example of the first main filter path section is the main filter path section 116 in FIG. 1. An example of the first piezoelectric substrate is the piezoelectric substrate 108 in FIG. 1. An example of the first one or more acoustic resonators are the acoustic resonators Ser1, Ser2, Shu1, Shu2 in FIG. 1.

An example of the first RF circuit package is the RF circuit package 204 in FIG. 2. An example of the first terminal is the terminal 214 in FIG. 2. An example of the first main filter path section is the main filter path section 216 in FIG. 2. An example of the first piezoelectric substrate is the piezoelectric substrate 208 in FIG. 2. An example of the one or more first acoustic resonators are the acoustic resonators Ser1, Shu1 in FIG. 2. Flow then proceeds to block 904.

At block 904, a second RF circuit package is formed. The second RF circuit package includes a second terminal externally accessible from the second RF circuit package; and a second piezoelectric substrate comprising one or more second acoustic resonators and a second main RF filter path section of the main RF filter path, the second main RF filter path section being coupled to the second terminal, wherein the first piezoelectric substrate is different than the second piezoelectric substrate. An example of the second RF circuit package is the RF circuit package 106 in FIG. 1. An example of the second terminal is the terminal 128 in FIG. 1. An example of the second main filter path section is the main filter path section 136 in FIG. 1. An example of the second piezoelectric substrate is the piezoelectric substrate 126 in FIG. 1. An example of the one or more second acoustic resonators are the acoustic resonators Ser3, Ser4, Ser5, Shu3, Shu4 in FIG. 1.

An example of the second RF circuit package is the RF circuit package 206 in FIG. 2. An example of the second terminal is the terminal 222 in FIG. 2. An example of the second main filter path section is the main filter path section 230 in FIG. 2. An example of the second piezoelectric substrate is the piezoelectric substrate 220 in FIG. 2. An example of the second one or more acoustic resonators are the acoustic resonators Ser2, Ser3, Ser4, Ser5, Shu2, Shu3, Shu4 in FIG. 2. Flow then proceeds to block 906.

At block 906, the first terminal of the first RF circuit package is coupled to the second terminal of the second RF circuit package such that the main RF filter path extends between the first terminal of the first RF circuit package and the second terminal of the second RF circuit package.

FIG. 10 illustrates a user element 1000, in accordance with some embodiments.

With reference to FIG. 10, the concepts described above may be implemented in various types of the user element 1000, such as mobile terminals, smart watches, tablets, computers, navigation devices, access points, and like wireless communication devices that support wireless communications, such as cellular, wireless local area network (WLAN), Bluetooth, and near field communications. The user element 1000 will generally include a control system 1002, a baseband processor 1004, transmit circuitry 1006, receive circuitry 1008, antenna switching circuitry 1010, multiple antennas 1012, and user interface circuitry 1014. In a non-limiting example, the control system 1002 may be a field-programmable gate array (FPGA) or an application-specific integrated circuit (ASIC). In this regard, the control system 1002 may include at least a microprocessor(s), an embedded memory circuit(s), and a communication bus interface(s). The receive circuitry 1008 receives radio frequency signals via the antennas 1012 and through the antenna switching circuitry 1010 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 1004 processes the digitized received signal to extract the information or data bits conveyed in the received signal. This processing typically comprises demodulation, decoding, and error correction operations, as will be discussed in greater detail below. The baseband processor 1004 is generally implemented in one or more digital signal processors (DSPs) and application specific integrated circuits (ASICs).

For transmission, the baseband processor 1004 receives digitized data, which may represent voice, data, or control information, from the control system 1002, which it encodes for transmission. The encoded data is output to the transmit circuitry 1006, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 1012 through the antenna switching circuitry 1010. The multiple antennas 1012 and the replicated transmit and receive circuitries 1006, 1008 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

What is claimed is:

1. A radio frequency (RF) filter circuit, comprising:
a first RF circuit package, comprising:
a first terminal externally accessible from the first RF circuit package; and
a first piezoelectric substrate comprising one or more first acoustic resonators and a first main RF filter path section of a main RF filter path, the first main RF filter path section is coupled to the first terminal; and
a second RF circuit package, comprising:
a second terminal externally accessible from the second RF circuit package, wherein the first terminal of the first RF circuit package is coupled to the second terminal of the second RF circuit package such that the main RF filter path is extended between the first terminal of the first RF circuit package and the second terminal of the second RF circuit package; and
a second piezoelectric substrate comprising one or more second acoustic resonators and a second main RF filter path section of the main RF filter path, the second main RF filter path section is coupled to the second terminal, wherein the first piezoelectric substrate is different than the second piezoelectric substrate.

2. The RF filter circuit of claim 1, wherein the first piezoelectric substrate is made from aluminum nitride (AlN) and the second piezoelectric substrate is also made from AlN, wherein the first piezoelectric substrate has a higher Scandium (Sc) doping than the second piezoelectric substrate so that the first piezoelectric substrate is different than the second piezoelectric substrate.

3. The RF filter circuit of claim 1, wherein the first piezoelectric substrate is made from aluminum nitride (AlN) and the second piezoelectric substrate is also made from AlN, wherein the first piezoelectric substrate has Scandium (Sc) doping and the second piezoelectric substrate has no SC doping so that the first piezoelectric substrate is different than the second piezoelectric substrate.

4. The RF filter circuit of claim 1, wherein the first piezoelectric substrate is made from aluminum nitride (AlN) and the second piezoelectric substrate is also made from AlN, wherein the first piezoelectric substrate has a first Scandium (Sc) doping and the second piezoelectric substrate has a second Sc doping wherein the first Sc doping is higher than the second Sc doping so that the first piezoelectric substrate is different than the second piezoelectric substrate.

5. The RF filter circuit of claim 1, wherein the first RF circuit package further comprises a third terminal externally accessible from the first RF circuit package, wherein the first main RF filter path section of the main RF filter path is coupled between the third terminal and the first terminal.

6. The RF filter circuit of claim 5, wherein the second RF circuit package further comprises a fourth terminal externally accessible from the second RF circuit package, wherein the second main RF filter path section of the main RF filter path is coupled between the second terminal and the fourth terminal.

7. The RF filter circuit of claim 6, wherein:
the one or more first acoustic resonators comprise one or more first series resonators connected within the first main RF filter path section; and
a first shunt path is connected in shunt with respect to the first main RF filter path section, the one or more first acoustic resonators comprising at least one shunt resonator connected within the first shunt path.

8. The RF filter circuit of claim 7, wherein:
the one or more second acoustic resonators comprise one or more second series resonators connected within the second main RF filter path section; and
a second shunt path is connected in shunt with respect to the second main RF filter path section, the one or more second acoustic resonators comprising at least one second shunt resonator connected within the second shunt path.

9. The RF filter circuit of claim 7, wherein the third terminal is configured to be coupled to an external RF signal port.

10. The RF filter circuit of claim 7, wherein the third terminal is configured to be coupled to an external RF antenna port.

11. A method of manufacturing a radio frequency (RF) filter circuit, comprising:
forming a first RF circuit package, comprising:
a first terminal externally accessible from the first RF circuit package; and
a first piezoelectric substrate comprising one or more first acoustic resonators and a first main RF filter path section of a main RF filter path, the first main RF filter path section is coupled to the first terminal;
forming a second RF circuit package, comprising:
a second terminal externally accessible from the second RF circuit package; and
a second piezoelectric substrate comprising one or more second acoustic resonators and a second main RF filter path section of the main RF filter path, the second main RF filter path section is coupled to the second terminal, wherein the first piezoelectric substrate is different than the second piezoelectric substrate; and
coupling the first terminal of the first RF circuit package to the second terminal of the second RF circuit package such that the main RF filter path extends between the first terminal of the first RF circuit package and the second terminal of the second RF circuit package.

12. A user element comprising a radio frequency (RF) filter circuit, wherein the RF filter circuit comprises:
a first RF circuit package, comprising:
a first terminal externally accessible from the first RF circuit package; and
a first piezoelectric substrate comprising one or more first acoustic resonators and a first main RF filter path section of a main RF filter path, the first main RF filter path section is coupled to the first terminal; and
a second RF circuit package, comprising:
a second terminal externally accessible from the second RF circuit package, wherein the first terminal of the first RF circuit package is coupled to the second terminal of the second RF circuit package such that the main RF filter path is extended between the first terminal of the first RF circuit package and the second terminal of the first RF circuit package; and
a second piezoelectric substrate comprising one or more second acoustic resonators and a second main RF filter path section of the main RF filter path, the second main RF filter path section is coupled to the second terminal, wherein the first piezoelectric substrate is different than the second piezoelectric substrate.

13. The user element of claim 12, wherein the first piezoelectric substrate is made from aluminum nitride (AlN) and the second piezoelectric substrate is also made from AlN, wherein the first piezoelectric substrate has a higher Scandium (Sc) doping than the second piezoelectric substrate so that the first piezoelectric substrate is different than the second piezoelectric substrate.

14. The user element of claim 12, wherein the first piezoelectric substrate is made from aluminum nitride (AlN) and the second piezoelectric substrate is also made from AlN, wherein the first piezoelectric substrate has Scandium (Sc) doping and the second piezoelectric substrate has no SC doping so that the first piezoelectric substrate is different than the second piezoelectric substrate.

15. The user element of claim 12, wherein the first piezoelectric substrate is made from aluminum nitride (AlN) and the second piezoelectric substrate is also made from AlN, wherein the first piezoelectric substrate has a first Scandium (Sc) doping and the second piezoelectric substrate has a second Sc doping wherein the first Sc doping is higher than the second Sc doping so that the first piezoelectric substrate is different than the second piezoelectric substrate.

16. The user element of claim 12, wherein the first RF circuit package further comprises a third terminal externally accessible from the first RF circuit package, wherein the first main RF filter path section of the main RF filter path is coupled between the third terminal and the first terminal.

17. The user element of claim 16, wherein the second RF circuit package further comprises a fourth terminal externally accessible from the second RF circuit package, wherein the second main RF filter path section of the main RF filter path is coupled between the second terminal and the fourth terminal.

18. The user element of claim 17, wherein:
the one or more first acoustic resonators comprise one or more first series resonators connected within the first main RF filter path section; and
a first shunt path is connected in shunt with respect to the first main RF filter path section, the one or more first acoustic resonators comprising at least one shunt resonator connected within the first shunt path.

19. The user element of claim 18, wherein:
the one or more second acoustic resonators comprise one or more second series resonators connected within the second main RF filter path section; and
a second shunt path is connected in shunt with respect to the second main RF filter path section, the one or more second acoustic resonators comprising at least one second shunt resonator connected within the second shunt path.

20. The user element of claim 17, wherein the third terminal is configured to be coupled to an external RF signal port.
